(19) United States
(12) Patent Application Publication
(10) Pub. No.: US 2015/0118514 A1
(43) Pub. Date: Apr. 30, 2015

(54) High Performance Thermal Interface System With Improved Heat Spreading and CTE Compliance

(71) Applicant: Teledyne Scientific & Imaging, LLC., Thousand Oaks, CA (US)

(72) Inventors: Yuan Zhao, Thousand Oaks, CA (US); Dennis R. Strauss, Ventura, CA (US); Ten-Luen T. Liao, South Pasadena, CA (US); Vivek Mehrotra, Simi Valley, CA (US); Chung-Lung Chen, Thousand Oaks, CA (US)

(21) Appl. No.: 14/067,684

(22) Filed: Oct. 30, 2013

(51) Int. Cl. H01L 23/373; B32B 3/28; B23K 1/20; B32B 7/12; F28F 3/10; B23K 1/00; B32B 9/00; B32B 15/01

(52) U.S. Cl. CPC H01L 23/3735; B32B 9/007; B32B 3/28; B32B 15/01; B32B 7/12; F28F 3/10; B23K 1/0008; B23K 1/20; B32B 2250/03; B32B 2250/04; B32B 2250/42; B32B 2255/06; B32B 2255/205; B32B 2307/302; B32B 2311/22; B32B 2311/30; B32B 2313/04; B32B 2457/00; B23K 2001/12
USPC 428/603; 428/408; 428/184; 428/181; 428/648; 29/890.054; 228/121

(57) ABSTRACT

A method of thermal interface material (TIM) assembly includes plating a seed layer on each of a plurality of graphite film layers, each of the graphite film layers comprising parallel-oriented graphite nanoplates, stacking the plurality of graphite film layers, each of the plurality of graphite film layers separated by at least one solder layer, pressing together the stacked graphite film layers, and applying heat to the plurality of graphite film layers and respective at least one solder layer in a vacuumed furnace to form a graphite laminate.

### STATEMENT REGARDING FEDERALLY SPONSORED RESEARCH OR DEVELOPMENT

This invention was made with Government support under Prime Contract No. N66001-09-C-2015 awarded by Defense Advanced Research Projects Agency (DARPA). The Government has certain rights in this invention.

### BACKGROUND

1. Field of the Invention

The invention relates to thermal interface, and more particularly to highly conductive terminals support in a matrix.

2. Description of the Related Art

Thermal interface materials (TIMs) typically play at least two roles in microelectronics packaging: 1) thermally bridging gaps between electronics devices and their heat sink, and 2) providing reliable bonds between two solid surfaces that typically have different coefficients of thermal expansion. High-power microelectronics typically require active or passive cooling using a heat sink. Thermal interface materials (TIMs) play a critical role in thermally coupling the power electronics to the heat sink. TIMs may employ solder or high-viscosity, low vapor-pressure organic liquids mixed with higher thermal-conductivity micro- or nanoparticles. Other TIM solutions may replace the micro or nano particles with thin wires or platelets with ultra-high thermal conductivity, such as carbon fibers (CFs), carbon nanotubes (CNTs), and graphite nano platelets (GNPs) to increase the effective thermal conductivity (K) of the TIM.

A need still exists to improve the effective thermal conductivity (K) of TIMs while maintaining and improving CTE compliance to provide more effective heat transfer between electronics devices and their respective heat sink.

### SUMMARY

A method of thermal interface material (TIM) assembly includes plating a seed layer on each of a plurality of graphite film layers, each of the graphite film layers comprising parallel-oriented graphite nanoplates, stacking the plurality of graphite film layers, each of the plurality of graphite film layers separated by at least one solder layer, pressing together the stacked graphite film layers, and applying heat to the plurality of graphite film layers and respective at least one solder layer in a vacuumed furnace to form a graphite laminate. The method may also include plating a solder layer on each respective seed layer prior to the pressing together step. In such an embodiment, the solder layer may include a tin (Sn)-based solder, and may include dicing the graphite laminate perpendicular to a plane defined by the plurality of graphite film layers and plating a laminate seed layer on a diced surface of the graphite laminate to form a laminate bonding surface. In such an embodiment, the method may further include dipping the graphite laminate in an epoxy prior to the dicing step to form a protective encapsulate about the graphite laminate and may include deforming each one of the plurality of graphite film layers into a predetermined non-planar layer shape. The predetermined non-planar layer shape may be selected from the group consisting of wavy, saw-toothed, or sinusoidal. The predetermined non-planar layer shape may have wavy top and wavy bottom surfaces, and adjacent layers of the stacked plurality of graphite film layers may have complementary shapes that nest together during the stacking step. Also, the deforming step may include passing each one of the plurality of graphite film layers through opposing rollers, the rollers having complementary protrusions to deform the plurality of graphite film layers. The deforming step may be accomplished prior to the stacking step.

In another embodiment, the method may include placing a solder preform layer between adjacent graphite film layers in the plurality of graphite film layers, and may include dicing the graphite laminate perpendicular in a plane defined by the plurality of graphite film layers and plating a laminate seed layer on a diced surface of graphite laminate to form a laminate bonding surface. In such an embodiment, the method may include dipping the graphite laminate in epoxy prior to the dicing step to form a protective encapsulate about the plurality of graphite film layers.

Another method of thermal interface material (TIM) assembly includes providing a seed layer on top and bottom surfaces of a graphite film layer, stacking the plurality of graphite film layers, providing a solder layer on at least one of the top and bottom surfaces of each of the plurality of graphite film layers, pressing together the stacked plurality of graphite film layers; and applying heat to the graphite film layers in a vacuumed furnace, the applying heat configured to bond the respective solder layer to the opposing exterior seed layers to form a graphite laminate. In one embodiment, the providing a solder layer step includes positioning a solder preform on at least one of the top and bottom surfaces of each of the plurality of graphite film layers. The providing a solder layer step may include plating a solder layer onto at least one of the top and bottom surfaces of each of the plurality of graphite film layers.

Another method of thermal interface material (TIM) assembly includes plating a seed layer on each of top and bottom surfaces of a plurality of graphite film layers, deforming each of the plurality of graphite film layers so that the top and bottom surfaces have a wavy surface, stacking the plurality of graphite film layers with a layer of solder in between adjacent layers of the plurality of wavy graphite film layers, pressing together the stacked plurality of graphite film layers, and applying heat to the graphite film layers in a vacuumed furnace to bond adjacent layers in the stacked plurality of graphite film layers to form a graphite laminate. Such embodiment may be defined wherein the layer of solder between adjacent layers of the plurality of wavy graphite film layers may be a Tin (Sn) layer bonded to at least one of the adjacent layers using electroplating. The layer of solder between adjacent layers of the plurality of wavy graphite film layers may be a solder preform positioned between the adjacent layers.

An apparatus includes a plurality of stacked graphite film layers, opposing surfaces of the plurality of stacked graphite layers having a respective plated seed layer and a respective solder layer between each respective opposing plated seed layers. In such an embodiment, each of the plurality of stacked graphite film layers may define a non-planar layer shape selected from the group consisting of wavy, saw-toothed, or sinusoidal shapes. Or, each of the plurality of stacked graphite film layers may have wavy top and wavy bottom surfaces and wherein adjacent layers of the stacked plurality of graphite film layers have complementary shapes that are configured to nest together when stacked. Each of the respective plated seed layers may be selected from the group consisting of nickel (Ni), cobol (Co), and iron (Fe). In one embodiment, the respective solder between each respective opposing plated seed layers may be plated solder.

Another apparatus includes a plurality of stacked metal film layers, opposing surfaces of the plurality of stacked metal layers having a respective plated seed layer, and a respective solder layer between each respective opposing plated seed layers. In such an embodiment, each of the plurality of stacked metal film layers may define a non-planar layer shape selected from the group consisting of wavy, saw-toothed, or sinusoidal shapes. Each of the plurality of stacked metal film layers may have wavy top and wavy bottom surfaces, and adjacent layers of the stacked plurality of metal film layers may have complementary shapes that are configured to nest together when stacked. In another embodiment, each of the respective plated seed layers is selected from the group consisting of nickel (Ni), cobol (Co), and iron (Fe). Also, the respective solder between each respective opposing plated seed layers may be plated solder.

### BRIEF DESCRIPTION OF THE DRAWINGS

The components in the FIGS. are not necessarily to scale, emphasis instead being placed upon illustrating the principals of the invention. Like reference numerals designate corresponding parts throughout the different views.

FIG. 1 is a flow chart illustrating a process to form a graphite laminate using a solder layer on a seed layer;

FIG. 2 is a flow chart illustrating a process to form a graphite laminate using a solder preform layer on a seed layer;

FIG. 3 is a flow chart illustrating a process to form a graphite laminate bonding surface;

FIG. 4 is an exploded perspective view of the components of one embodiment, a graphite laminate that is formed with solder preform and two plated soldering layers between adjacent graphite layers;

FIG. 5 is an exploded perspective view of a graphite laminate that is formed with a solder preform and only a single plated soldering layer disposed between adjacent graphite layers;

FIG. 6 is an exploded perspective view of a graphite laminate formed with a solder preform disposed between adjacent graphite layers, without the benefit of plated solder layers on the graphite layers;

FIG. 7 is an exploded perspective view of a graphite laminate that is formed with plated soldering layers disposed between adjacent graphite layers;

FIG. 8 illustrates the graphite laminate in FIG. 6 seated on a heat sink and positioned in complementary opposition to a heat source;

FIG. 9 is a cross sectional view of one embodiment of a graphite composite thermally coupled between a heat source and a sink for communication of excess heat away from the heat source;

FIG. 10 is an exploded perspective view of another embodiment of a graphite laminate that is formed with a solder preform disposed between adjacent graphite layers without the benefit of plated solder layers on the graphite layers; and

FIG. 11 is an exploded perspective view of the graphite laminate in FIG. 10 that is seated on a heat sink and positioned in complementary opposition to a heat source.

### DETAILED DESCRIPTION

A system that includes a novel thermal interface material (TIM) is disclosed that provides high in-plane thermal conductivity for heat spreading while avoiding CTE mismatching issues. The thermal interface material assembly may include laminated graphite film layers. Seed layers may be plated on opposing graphite film layers with each of the graphite film layers separated by least one solder layer. A compression and heat treatment may be used to form a graphite laminate from the graphite film layers, seed layers and at least one solder layer, with an epoxy dip used as a protective encapsulate for the structure. A final dicing may be made perpendicular to a plane defined by the graphite film layers, and a plating of laminate seed layer may be made on the surfaces exposed by the dicing to provide a laminate bonding surface.

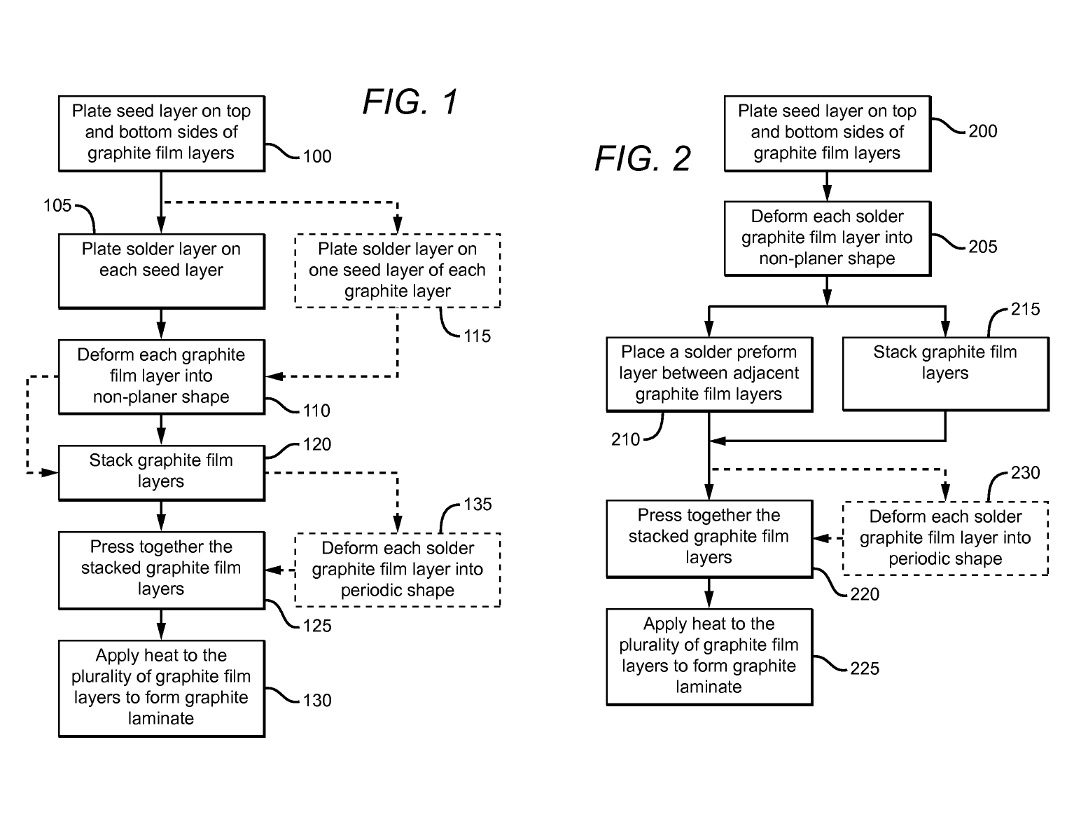

FIG. 1 illustrates one embodiment of a process for forming a graphite laminate for use as a TIM. A nickel (Ni) metallization layer, referred to herein as a “seed layer,” may be electroplated onto the top and bottom sides of a plurality of graphite film layers (block 100) to a thickness of approximately 150-500 nm. In one embodiment, the graphite layers may be HITHERM™ HT-705 graphite layers each having a thickness of approximately 127 microns, linear in-plane CTE of −0.400 um/m-° C. and thermal in-plane conductivity of 150 W/m-K. A tin (Sn)-based solder layer may be plated on each respective seed layer (block 105) to a thickness of approximately 1-10 microns. The seed layer is preferably a Ni metallization layer, but may be a cobalt, iron or other metal-based seed layer material to facilitate bonding between the graphite film layer and the solder layer. The graphite film layers may be generally characterized as having parallel-oriented graphite nanoplates. In an alternative embodiment, a solder layer is plated on only one side of each graphite layer (block 115), rather than on both top and bottom sides. In one embodiment, the solder layers referred to herein may be tin (Sn)-based, such as Indalloy 121 (96.5% Sn and 3.5% Ag) offered by Indium Corporation of Chicago, Ill. In other embodiments, other solders for the solder layer may be used, depending on the desired service and reflow temperatures.

Each graphite film layer (with its seed and solder layers) may be deformed into complementary and periodic non-planar shapes (block 110), such as a regular and generally sinusoidal wavy shape or saw-toothed shape. The deformation process may use a press that receives each graphite film layer between opposing and complementary rollers that have protrusions, ribs or other structures to deform each graphite film layer into the wavy shape. The graphite film layers may be stacked and nested together, one on top of each other (block 120), and pressed together (block 125) at approximately 30 psi. If the graphite film layers were deformed into non-planar shapes, the pressing step may use a mold having internal top and bottom shapes that approximate the non-planar shape of the component layers of the graphite laminate. Heat may be applied within a vacuum furnace and during the pressing step to bring the solder layers to a temperature of approximately 10°-30° below its solder melt point for approximately 30 minutes to 1 hour to accomplish a diffusion bond between layers to form a graphite laminate (block 130). If Indalloy 121 solder is used, the heating step would peak at approximately 191° C.-211° C. (221° C. melting point) within the solder areas of the graphite laminate to cause a diffusion bond between layers.

If deformed, the previously-formed wavy shape of the component layers (graphite, seed and solder layers) of the graphite laminate greatly reduce the shear strain and stress in the “horizontal” direction induced by CTE mismatch during use. The wavy shape of the graphite film, graphite seed and solder layers also significantly improves the heat spreading effect in the vertical direction. As used herein, “horizontal” is intended to refer to the general plane of the graphite layers, while “vertical” is intended to refer to a direction perpendicular to the plane of the graphite layers. In an alternative embodiment, the stacked graphite film layers are deformed into a non-planar shape after stacking rather than deformed prior to stacking (block 135) to form stacked and nested shapes.

FIG. 2 illustrates another embodiment of a process for forming a graphite laminate. A seed layer is plated on top and bottom sides of a plurality of graphite film layers (block 200. Rather than providing for a plated solder layer on the seed layers, each graphite film layer may be deformed into a non-planar shape (block 205), such as a wavy shape. A solder preform layer may be placed between adjacent graphite film layers (block 210) as the graphite film layers are stacked (block 215), and each solder preform layer may have a thickness of approximately 50 microns. The stacked graphite film layers may be pressed together (block 220) and heat may be applied to the plurality of graphite film layers to cause a diffusion bond between the solder preform layer, plated solder layer and seed layers to form a graphite laminate (block 225) as the structure cools. In an alternative embodiment, the stacked graphite film layers may be deformed into a non-planar shape after stacking rather than prior to stacking (block 230).

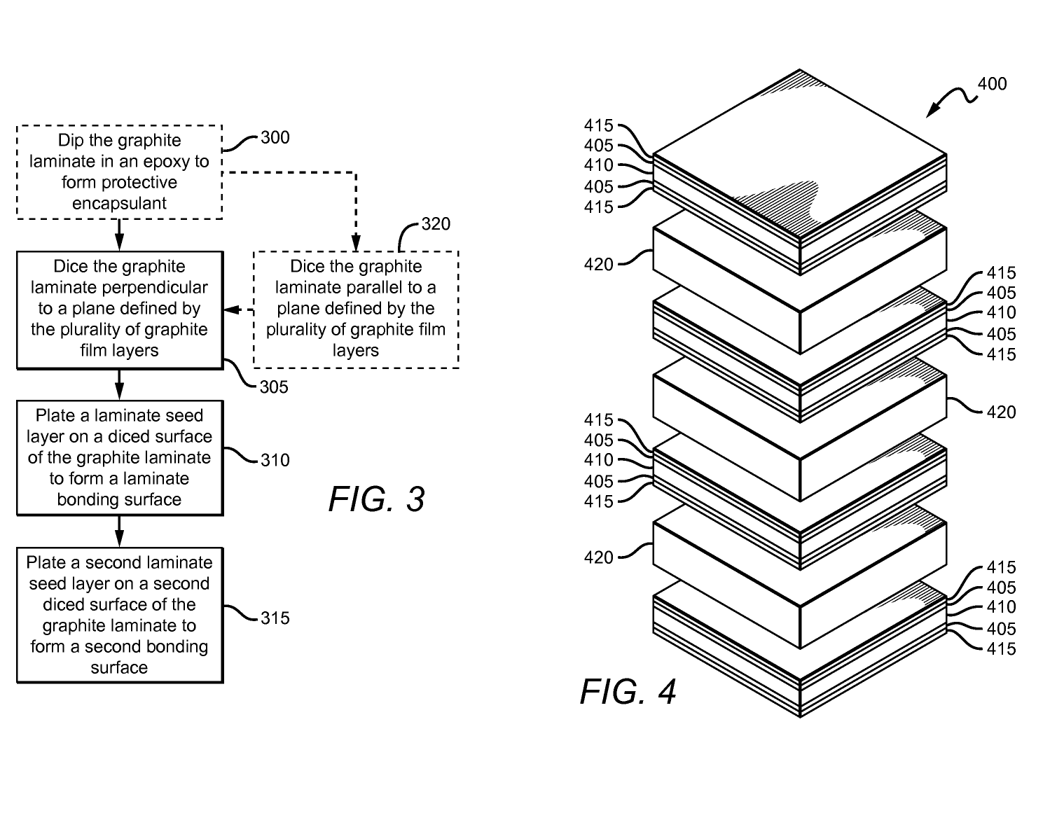

FIG. 3 illustrates one embodiment of a process for using either the graphite laminate described in either FIG. 1 or FIG. 2 to establish a laminate bonding surface for bonding to a heat source and heat sink. The graphite laminate may be dipped in an epoxy to form a protective encapsulate about the graphite laminate (block 300). The laminate is diced perpendicular to a plane defined by the plurality of graphite film layers (block 305). A laminate seed layer on one of the diced surfaces of the graphite laminate may be plated to form a laminate bonding surface (block 310) and a full second laminate seed layer may be plated on a second diced surface of the graphite laminate to form a second bonding surface (block 315). In an alternative embodiment, the graphite laminate is diced parallel to a plane defined by the plurality of graphite film layers (block 320).

FIG. 4 is an exploded perspective view of the components of one embodiment a graphite laminate that is formed with solder preform and two plated soldering layers between adjacent graphite layers. The graphite laminate 400 is illustrated composed of planar graphite layers or graphite layers illustrated prior to deformation into non-planar shapes. The graphite laminate is illustrated as it may exist before a pressing and heating step to couple the components of the graphite laminate together. A seed layer 405 may be disposed on each of top and bottom surfaces of a plurality of graphite layers 410 to accept a solder layer. A plated solder layer 415 may be disposed over all or substantially all of each seed layer 410. A solder preform layer 420 may be aligned with and disposed between adjacent solder layers 415 of adjacent graphite layers 410. In the illustrated embodiment, the graphite layers 410 and respective seed and solder layers (405, 415) are illustrated as generally rectangular and planar. However, the graphite layers and associated plated layers (405, 415) may form other planar shapes such as a circle, triangle, or other polygonal shape.

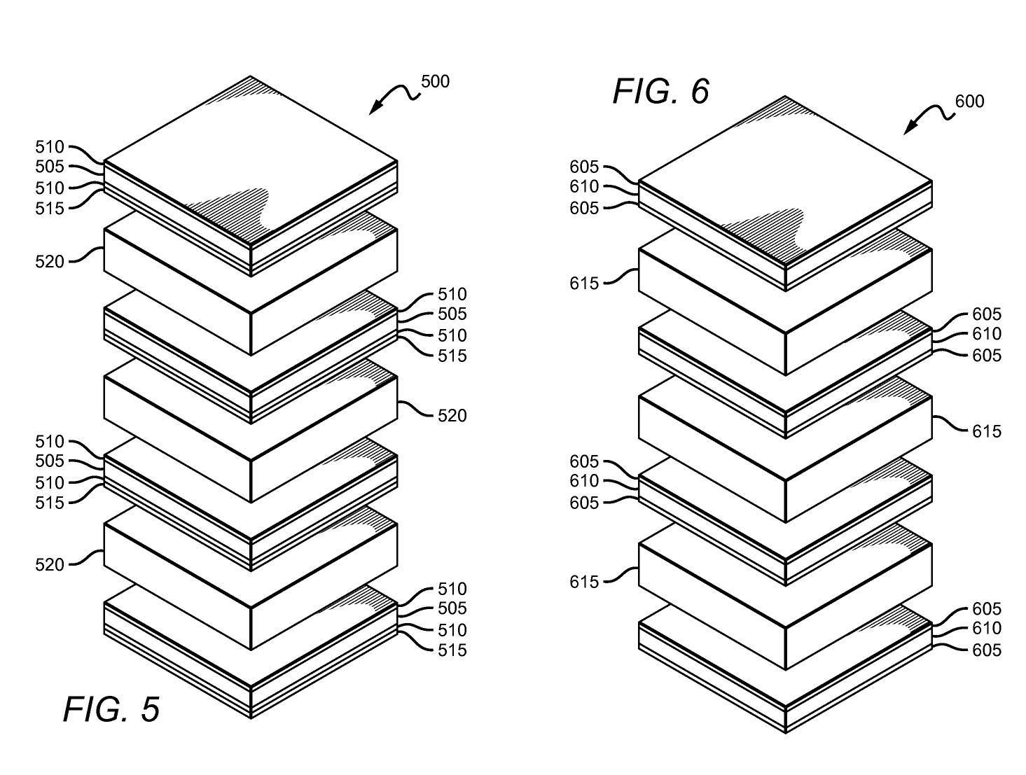

FIG. 5 is an exploded perspective view of a graphite laminate that is formed with a solder preform and only a single plated soldering layer disposed between adjacent graphite layers. Similar to the graphite laminate first illustrated in FIG. 4, the graphite laminate 500 is illustrated as components as the graphite laminate may exist before a pressing and heating step that couples the components of the graphite laminate together. A plurality of graphite layers 505 may have their top and bottom surfaces each plated with a seed layer 510. A plated solder layer 515 may be disposed over all or substantially all of one of the seed layers 510 on each graphite layer 505. A solder preform layer 520 may be aligned with and disposed between adjacent seed and plated solder layers (510, 515) of the adjacent graphite layers 505. The graphite laminate 500 is illustrated composed of planar graphite layers or graphite layers prior to the formation into non-planar shapes.

FIG. 6 is an exploded perspective view of another embodiment of a graphite laminate that is formed with a solder preform disposed between adjacent graphite layers without the benefit of plated solder layers on the graphite layers. The graphite laminate 600 is illustrated with planar graphite layers or graphite layers prior to the formation into non-planar shapes, and is illustrated as it may exist before a pressing and heating step to couple the components of the graphite laminate together. A seed layer 605 is disposed on each of top and bottom surfaces of a plurality of graphite layers 610. A solder preform layer 615 may be aligned with and disposed between adjacent seed layers 605 of adjacent graphite layers 610. Although the graphite layers 610 and respective seed layers 605 are illustrated as generally rectangular and planar, the graphite layers and seed layers (610, 605) may form other planar shapes such as a circle, triangle, or other polygonal shapes.

In other embodiments, copper layers, gold layers, aluminum layers or other metal film layers that have high thermal conductivity may replace the graphite layers described and illustrated in FIGS. 4-6.

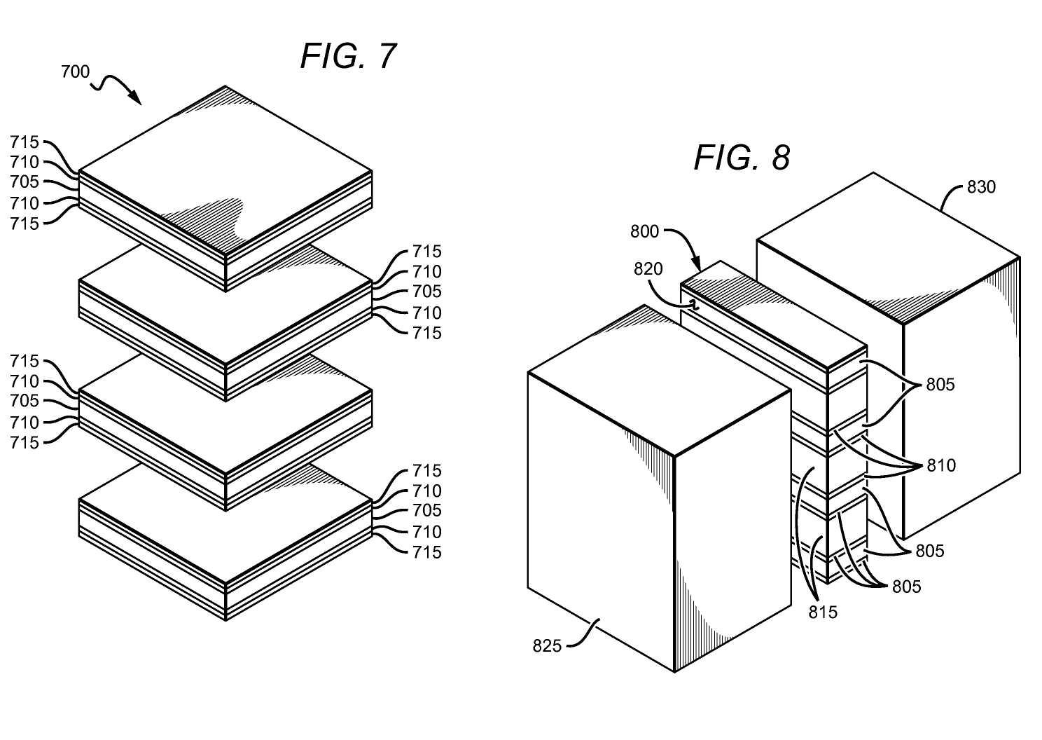

FIG. 7 is an exploded perspective view of a graphite laminate that is formed with plated soldering layers disposed between adjacent graphite layers. Similar to the graphite laminates illustrated in FIGS. 4-6, the graphite laminate 700 is illustrated as having layered components as the graphite laminate may exist before a pressing and heating step that couples the components of the graphite laminate together. A plurality of graphite layers 705 may have their top and bottom surfaces each plated with a seed layer 710. A plated solder layer 715 may be disposed over all or substantially all of one of the seed layers 710 on each graphite layer 705. The graphite laminate 700 is illustrated composed of planar graphite layers or graphite layers prior to the formation into non-planar shapes.

FIGS. 4-7 illustrate different embodiments of a graphite laminate. In each embodiment, the graphite layers may be HITHERM™ HT-705 graphite layers each having a thickness of approximately 127 microns, linear in-plane CTE of −0.400 um/m-° C. and thermal in-plane conductivity of 150 W/m-K. Other graphite layers may also be used, either alone or in combination to achieve different thermal conductivity, such as HITHERM™ HT-1205 or other commercially-available graphite TIM films such as graphite films that are 150-200 microns thick. The seed layers may be a nickel (Ni) metallization layer and may have a thickness of approximately 150-500 nm. Described solder layers may have a thickness of approximately 1-10 microns and solder preform layers a thickness of approximately 50 microns. Each solder layer or solder preform layer may be tin (Sn)-based, such as Indalloy 121 (96.5% Sn and 3.5% Ag) offered by Indium Corporation of Chicago, Ill., however, other solders may be used to vary the desired service and reflow temperatures. Also, although thicknesses are described herein for the graphite, seed, solder and solder preform layers (such as 410, 405, 415, 420), the ratio of graphite to solder volume (graphite %:solder %) may vary from 90%:10% to 40%:60%.

FIG. 8 illustrates the graphite laminate in FIG. 6 seated on a heat sink and positioned in complementary opposition to a heat source. The graphite composite 800 may be formed with a plurality of graphite film layers 805, with respective seed layers 810 on top and bottom surfaces of each respective graphite film layer 805. The graphite composite 800 may have a solder layer 815 disposed between opposing seed layers 810. The exposed face of the graphite composite may be a bonding surface 820 to receive a complimentary bonding surface of the heat source 825 so that heat generated from the heat source 825 is thermally conducted through the graphite laminate 800 for communication to the heat sink 830 to provide removal of excess heat from the heat source 825. In an alternative embodiment, there may be more than one heat source for seating on the graphite composite so a single graphite composite may be used too cool multiple heat sources.

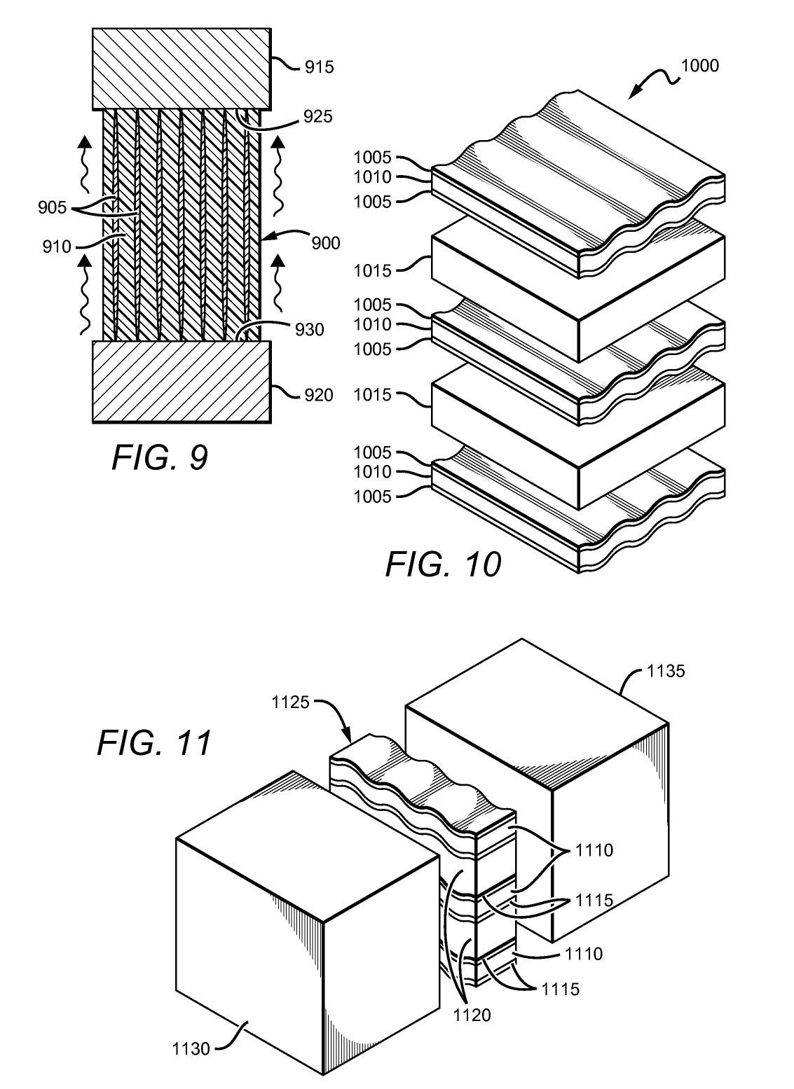

FIG. 9 is a cross sectional view of one embodiment of a graphite composite thermally coupled between a heat source and a sink for communication of excess heat away from the heat source. The graphite composite 900 has a plurality of graphite layers 905 in a solder matrix 910 that may be formed from one or more of a solder preform disposed between adjacent graphite layers, a single plated solder layer between adjacent graphite layers or two plated solder layers between adjacent graphite layers. The graphite layers 905 are oriented perpendicular to a heat sink 915 and a heat source 920 and substantially span the distance between them to provide for effective thermal transfer in the plane defined by the graphite layers 905. In a preferred embodiment, the graphite layers 905 are in direct thermal communication with both the heat sink 920 and heat source 915 at 1st and 2nd bonding surfaces (925, 930).

FIG. 10 is an exploded perspective view of another embodiment of a graphite laminate that is formed with a solder preform disposed between adjacent graphite layers without the benefit of plated solder layers on the graphite layers. The graphite laminate 1000 is illustrated with graphite layers that have been formed into non-planar shapes, and is illustrated as it may exist before a pressing and heating step to couple the components of the graphite laminate together. A seed layer 1005 is disposed on each of top and bottom surfaces of a plurality of graphite layers 1010. A solder preform layer 1015 may be aligned with and disposed between adjacent seed layers 1005 of adjacent graphite layers 1010. Although the graphite layers 1010 and respective seed layers 1005 are illustrated as generally rectangular and planar, the graphite layers and seed layers (1010, 1005) may form other planar shapes such as a circle, triangle, or other polygonal shapes.

FIG. 11 is an exploded perspective view of the graphite laminate in FIG. 10 that is seated on a heat sink and positioned in complementary opposition to a heat source. The graphite composite 1105 may be formed with a plurality of graphite film layers 1110, with respective seed layers 1115 on top and bottom surfaces of each respective graphite film layer 1110. The graphite composite 1105 may have a solder layer 1120 disposed between opposing seed layers 1115. The exposed face of the graphite composite may be a bonding surface 1125 to receive a complimentary bonding surface of the heat source 1130 so that heat generated from the heat source 1130 is thermally conducted through the graphite composite 1105 for communication to the heat sink 1135 to provide removal of excess heat from the heat source 1130. In an alternative embodiment, there may be more than one heat source for seating on the graphite composite 1105 so a single graphite composite 1105 may be used too cool multiple heat sources.

We claim:

1. A method of thermal interface material (TIM) assembly, comprising:
plating a seed layer on each of a plurality of graphite film layers, each of the graphite film layers comprising parallel-oriented graphite nanoplates;
stacking the plurality of graphite film layers, each of the plurality of graphite film layers separated by at least one solder layer;
pressing together the stacked graphite film layers; and
applying heat to the plurality of graphite film layers and respective at least one solder layer in a vacuumed furnace to form a graphite laminate.

2. The method of claim 1, further comprising:
plating a solder layer on each respective seed layer prior to the pressing together step.

3. The method of claim 2, wherein the solder layer comprises a tin (Sn)-based solder.

4. The method of claim 2, further comprising:
dicing the graphite laminate perpendicular to a plane defined by the plurality of graphite film layers; and
plating a laminate seed layer on a diced surface of the graphite laminate to form a laminate bonding surface.

5. The method of claim 4, further comprising:
dipping the graphite laminate in an epoxy prior to the dicing step to form a protective encapsulate about the graphite laminate.

6. The method of claim 5, further comprising:
deforming each one of the plurality of graphite film layers into a predetermined non-planar layer shape.

7. The method of claim 6, wherein the predetermined non-planar layer shape is selected from the group consisting of wavy, saw-toothed, or sinusoidal.

8. The method of claim 6, wherein the predetermined non-planar layer shape has wavy top and wavy bottom surfaces and wherein adjacent layers of the stacked plurality of graphite film layers have complementary shapes that nest together during the stacking step.

9. The method of claim 6, wherein the deforming step comprises passing each one of the plurality of graphite film layers through opposing rollers, the rollers having complementary protrusions to deform the plurality of graphite film layers.

10. The method of claim 6, wherein the deforming step is accomplished prior to the stacking step.

11. The method of claim 1, further comprising:
placing a solder preform layer between adjacent graphite film layers in the plurality of graphite film layers.

12. The method of claim 11, further comprising:
dicing the graphite laminate perpendicular in a plane defined by the plurality of graphite film layers; and
plating a laminate seed layer on a diced surface of graphite laminate to form a laminate bonding surface.

13. The method of claim 12, further comprising:
dipping the graphite laminate in epoxy prior to the dicing step to form a protective encapsulate about the plurality of graphite film layers.

14. A method of thermal interface material (TIM) assembly, comprising:
providing a seed layer on top and bottom surfaces of a graphite film layer;
stacking the plurality of graphite film layers;
providing a solder layer on at least one of the top and bottom surfaces of each of the plurality of graphite film layers;
pressing together the stacked plurality of graphite film layers; and
applying heat to the graphite film layers in a vacuumed furnace, the applying heat configured to bond the respective solder layer to the opposing exterior seed layers to form a graphite laminate.

15. The method of claim 14, wherein the providing a solder layer step comprises positioning a solder preform on at least one of the top and bottom surfaces of each of the plurality of graphite film layers.

16. The method of claim 14, wherein the providing a solder layer step comprises plating a solder layer onto at least one of the top and bottom surfaces of each of the plurality of graphite film layers.

17. A method of thermal interface material (TIM) assembly, comprising:
plating a seed layer on each of top and bottom surfaces of a plurality of graphite film layers;
deforming each of the plurality of graphite film layers so that the top and bottom surfaces have a wavy surface;
stacking the plurality of graphite film layers with a layer of solder in between adjacent layers of the plurality of wavy graphite film layers;
pressing together the stacked plurality of graphite film layers; and
applying heat to the graphite film layers in a vacuumed furnace to bond adjacent layers in the stacked plurality of graphite film layers to form a graphite laminate.

18. The method of claim 17, wherein the layer of solder between adjacent layers of the plurality of wavy graphite film layers is a Tin (Sn) layer bonded to at least one of the adjacent layers using electroplating.

19. The method of claim 17, wherein the layer of solder between adjacent layers of the plurality of wavy graphite film layers is a solder preform positioned between the adjacent layers.

20. An apparatus, comprising:
a plurality of stacked graphite film layers, opposing surfaces of the plurality of stacked graphite layers having a respective plated seed layer; and
a respective solder layer between each respective opposing plated seed layers.

21. The apparatus of claim 20, wherein each of the plurality of stacked graphite film layers defines a non-planar layer shape selected from the group consisting of wavy, saw-toothed, or sinusoidal shapes.

22. The apparatus of claim 20, wherein each of the plurality of stacked graphite film layers has wavy top and wavy bottom surfaces and wherein adjacent layers of the stacked plurality of graphite film layers have complementary shapes that are configured to nest together when stacked.

23. The apparatus of claim 20, wherein each of the respective plated seed layers is selected from the group consisting of nickel (Ni), cobol (Co), and iron (Fe).

24. The apparatus of claim 20, wherein the respective solder between each respective opposing plated seed layers is plated solder.

25. An apparatus, comprising:
a plurality of stacked metal film layers, opposing surfaces of the plurality of stacked metal layers having a respective plated seed layer; and
a respective solder layer between each respective opposing plated seed layers.

26. The apparatus of claim 25, wherein each of the plurality of stacked metal film layers defines a non-planar layer shape selected from the group consisting of wavy, saw-toothed, or sinusoidal shapes.

27. The apparatus of claim 25, wherein each of the plurality of stacked metal film layers has wavy top and wavy bottom surfaces and wherein adjacent layers of the stacked plurality of metal film layers have complementary shapes that are configured to nest together when stacked.

28. The apparatus of claim 25, wherein each of the respective plated seed layers is selected from the group consisting of nickel (Ni), cobol (Co), and iron (Fe).

29. The apparatus of claim 25, wherein the respective solder between each respective opposing plated seed layers is plated solder.
